(19) United States
(12) Patent Application Publication
(10) Pub. No.: US 2024/0365632 A1
(43) Pub. Date: Oct. 31, 2024

(54) DISPLAY DEVICE AND METHOD FOR MANUFACTURING THE SAME

(71) Applicant: Samsung Display Co., Ltd., Yongin-si (KR)

(72) Inventor: CHANGMO KOO, Yongin-si (KR)

(21) Appl. No.: 18/402,560

(22) Filed: Jan. 2, 2024

(30) Foreign Application Priority Data
Apr. 28, 2023 (KR) 10-2023-0056160

(51) Int. Cl. H10K 59/38; H10K 59/12; H10K 59/35

(52) U.S. Cl. CPC H10K 59/38; H10K 59/1201; H10K 59/352

(57) ABSTRACT

A display device includes: a display panel comprising a light emitting element layer; a light converting panel on the display panel; and a filling layer between the display panel and the light converting panel, wherein the light converting panel includes: a light control layer comprising a division pattern, and a plurality of light controllers spaced apart from each other by the division pattern; and a cure control layer below the division pattern.

### CROSS-REFERENCE TO RELATED APPLICATIONS

The present application claims priority to and the benefit of Korean Patent Application No. 10-2023-0056160, filed on Apr. 28, 2023, the content of which in its entirety is herein incorporated by reference.

### BACKGROUND

### 1. Field

Aspects of some embodiments of the present disclosure herein relate to a display device and a method for manufacturing the same.

### 2. Description of Related Art

Various multimedia display devices such as televisions, mobile phones, tablet computers, and game consoles, include display panels and light converting panels in order to provide image information for users.

The display panels each include a light emitting element and a pixel circuit for driving the light emitting element. The light converting panels may each include a light controller using quantum dots, and source light provided from the light emitting element of the display panel may be converted by the light controller to be provided as light having various colors.

The display panel and the light converting panel may be coupled to each other through a filling layer. There is a need for research on the filling layer for reducing light losses until the source light provided from the display panel reach the light converting panel.

The above information disclosed in this Background section is only for enhancement of understanding of the background and therefore the information discussed in this Background section does not necessarily constitute prior art.

### SUMMARY

Aspects of some embodiments of the present disclosure herein relate to a display device and a method for manufacturing the same, and for example, to a display device including a filling layer and a method for manufacturing the display device.

Aspects of some embodiments of the present disclosure include a display device that includes a filling layer having a structure capable of reducing light losses to relatively improve light extraction efficiency and color reproducibility.

Aspects of some embodiments of the present disclosure also include a method for manufacturing a display device, the method having relatively improved process properties and mass productivity.

According to some embodiments of the present disclosure, a display device includes a display panel including a light emitting element layer, a light converting panel on the display panel, and a filling layer between the display panel and the light converting panel. According to some embodiments, the light converting panel includes a light control layer, which includes a division pattern and a plurality of light controllers spaced apart from each other by the division pattern, and a cure control layer below the division pattern.

According to some embodiments, the division pattern and the cure control layer may overlap each other on a plane.

According to some embodiments, the filling layer may include a filled portion overlapping the plurality of light controllers on a plane, and a void overlapping the division pattern on the plane, and the filled portion may have a refractive index greater than that of the void.

According to some embodiments, the cure control layer may include a cure retardant material.

According to some embodiments, the filling layer may include a filled portion overlapping the plurality of light controllers on a plane, and a void overlapping the division pattern on the plane, and the void may have a shape having a curvature on a cross section.

According to some embodiments, the filling layer may include a filled portion overlapping the plurality of light controllers on a plane, and a void overlapping the division pattern on the plane, and the void may have an oval shape on a cross section.

According to some embodiments, the cure control layer may have a top surface adjacent to the division pattern, and a bottom surface adjacent to the filling layer, and the bottom surface of the cure control layer may include an unevenness.

According to some embodiments, the filling layer may include a filled portion overlapping the plurality of light controllers on a plane, and a void overlapping the division pattern on the plane. According to some embodiments, the void may have a top surface adjacent to the cure control layer, and a bottom surface adjacent to the display panel, and the top surface of the void may have an area less than that of the bottom surface of the void on the plane.

According to some embodiments, the cure control layer may include a cure retardant material, and the cure control layer may have a top surface adjacent to the division pattern, and a bottom surface adjacent to the filling layer. According to some embodiments, the bottom surface of the cure control layer may include an unevenness.

According to some embodiments, the filling layer may include a filled portion overlapping the plurality of light controllers on a plane, and a void overlapping the division pattern on the plane. According to some embodiments, the void may have a top surface adjacent to the cure control layer, and a bottom surface adjacent to the display panel, and the top surface of the void may have an area less than that of the bottom surface of the void on the plane.

According to some embodiments of the present disclosure, a method for manufacturing a display device includes preparing a light converting panel, bonding a display panel to the light converting panel with a filling material therebetween, and curing the filling material. According to some embodiments, the preparing of the light converting panel includes forming a color filter layer on a base layer, forming, on the color filter layer, a light control layer including a division pattern and a plurality of light controllers spaced apart from each other by the division pattern, and forming a cure control layer on the division pattern.

According to some embodiments, the curing of the filling material may include an operation in which the filling material on the plurality of light controllers is cured and contracts, and the filling material on the division pattern is not cured.

According to some embodiments, the curing of the filling material may include an operation in which a filled portion overlapping the plurality of light controllers on a plane and a void overlapping the division pattern on the plane are formed.

According to some embodiments, the cure control layer may include a cure retardant material that retards the curing of the filling material.

According to some embodiments, the curing of the filling material may include an operation, in which a void overlapping the division pattern on a plane is formed, and the void may have a shape having a curvature on a cross section.

According to some embodiments, the void may have an oval shape on a cross section.

According to some embodiments, the cure control layer may include an unevenness on a surface thereof adjacent to the filling material.

According to some embodiments, the curing of the filling material may include an operation in which a filled portion overlapping the plurality of light controllers on a plane and a void overlapping the division pattern on the plane are formed. According to some embodiments, the void may have a top surface adjacent to the cure control layer, and a bottom surface adjacent to the display panel, and the top surface of the void may have an area that is formed to be less than that of the bottom surface of the void on the plane.

According to some embodiments, the bonding of the display panel to the light converting panel may include applying the filling material.

According to some embodiments, in the forming of the cure control layer, the cure control layer may be formed through a photolithography process.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1A is a perspective view of a display device according to some embodiments of the present disclosure;

FIG. 1B is a cross-sectional view of a display device according to some embodiments of the present disclosure;

FIG. 2 is a plan view of a display panel according to some embodiments of the present disclosure;

FIG. 3 is an equivalent circuit diagram of a pixel according to some embodiments of the present disclosure;

FIG. 4 is an enlarged plan view of a display area according to some embodiments of the present disclosure;

FIGS. 5 to 7 are each a cross-sectional view of a portion of a display device according to some embodiments of the present disclosure;

FIGS. 8A and 8B are each a cross-sectional view of an emission layer according to some embodiments of the present disclosure;

FIGS. 9A and 9B are each a flowchart of a method for manufacturing a display device according to some embodiments of the present disclosure; and

FIGS. 10 to 13 are each a cross-sectional view illustrating an operation of a method for manufacturing a display device according to some embodiments of the present disclosure.

### DETAILED DESCRIPTION

The present invention may be modified in various forms, and particular embodiments thereof will be illustrated in the drawings and described herein in detail. The inventive concept should not be construed as limited to the embodiments set forth herein. Rather, these embodiments are provided so that this disclosure will be thorough and complete, and will fully convey the scope of the inventive concept to those skilled in the art.

As used herein, the singular forms are intended to include the plural forms as well, unless the context clearly indicates otherwise.

It will be further understood that the terms such as “includes” and “has”, when used herein, specify the presence of stated features, numerals, steps, operations, elements, parts, or the combination thereof, but do not preclude the presence or addition of one or more other features, numerals, steps, operations, elements, parts, or the combination thereof.

It will be understood that when an element (or region, layer, section, etc.) is referred to as being “on”, “connected to” or “coupled to” another element, it can be located directly on, connected or coupled to the other element or a third intervening elements may be located between the elements.

In addition, the terms, such as “below”, “beneath”, “on” and “above”, are used for explaining the relation of elements shown in the drawings. These terms are relative concept and are explained based on the direction shown in the drawing.

In the present disclosure, when a member is referred to as being “located above” another member, the member would be oriented above or below the other member.

As used herein, “being directly located” may mean that there is no additional layer, film, region, plate or the like between a part such as a layer, film, region, plate or the like and another part. For example, “being directly located” may mean that two layers or two members are located with no additional member such as an adhesive member.

The term “and/or” used herein includes one or more combinations which may be defined by relevant elements.

It will be understood that, although the terms first, second, etc. may be used herein to describe various elements, these elements should not be limited by these terms. These terms are only used to distinguish one element from another element. For example, a first element could be termed a second element without departing from the teachings of the present invention, and similarly, a second element could be termed a first element.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Like reference numerals refer to like elements throughout. In addition, in the drawings, the thickness, the ratio, and the dimension of elements are exaggerated for effective description of the technical contents.

Hereinafter, a display device and a method for manufacturing the same according to some embodiments of the present disclosure will be described in more detail with reference to the accompanying drawings.

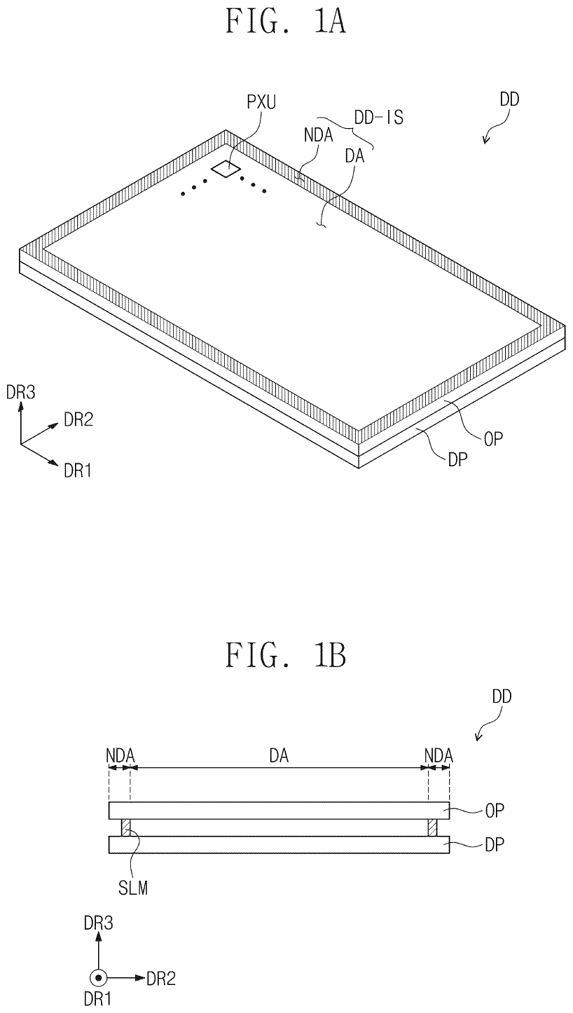

FIG. 1A is a perspective view of a display device DD according to some embodiments of the present disclosure. FIG. 1B is a cross-sectional view of the display device DD according to some embodiments of the present disclosure.

Referring to FIG. 1A, the display device DD may display an image IM through a display surface DD-IS. The display surface DD-IS may be parallel to a plane defined by a first direction DR1 and a second direction DR2. A top surface of a member, which is located at the uppermost side of the display device DD in a third direction DR3, may be defined as the display surface DD-IS.

The third direction DR3 may indicate a normal or perpendicular direction to the display surface DD-IS, i.e., a thickness direction of the display device DD. A front surface (or top surface) and a rear surface (or bottom surface) of each of layers or units to be described below may be defined based on the third direction DR3.

The display device DD may include a display area DA and a non-display area NDA. Unit pixels PXU are located in the display area DA, and unit pixels PXU are not located in the non-display area NDA. The non-display area NDA may be defined along an edge of the display surface DD-IS. The non-display area NDA may surround the display area DA. According to some embodiments of the present disclosure, the non-display area NDA may be omitted or located only at one side of the display area DA. Although FIG. 1A illustrates the flat display device DD as an example, the display device DD may have a curved shape, may be foldable, may be rollable, or may be slidable from a housing.

The unit pixels PXU illustrated in FIG. 1A may define a pixel row and a pixel column. Each of the unit pixels PXU is a minimal repeating unit, and the unit pixel PXU may include at least one pixel. The unit pixel PXU may include a plurality of pixels that provide light having different colors from each other.

Referring to FIG. 1B, the display device DD may include a display panel DP, and a light converting panel OP facing and spaced apart from the display panel DP. The display panel DP may be referred to as a lower display substrate, and the light converting panel OP may be referred to as an upper display substrate. A cell gap (e.g., a set or predetermined cell gap) may be provided between the display panel DP and the light converting panel OP. The cell gap may be maintained by a sealing member SLM that couples the display panel DP and the light converting panel OP to each other. The sealing member SLM may include a binder resin, and inorganic fillers mixed in the binder resin. The sealing member SLM may further include other additives. The additives may include an amine-based curing agent and a photoinitiator. The additives may further include a silane-based additive and an acrylic additive. The sealing member SLM may include an inorganic-based material such as frit.

In each of the display panel DP and the light converting panel OP, a display area DA and a non-display area NDA may be defined to substantially correspond to the display area DA and the non-display area NDA of the display device DD, respectively. Hereinafter, the display area DA of the display device DD may mean the display area DA of each of the display panel DP and the light converting panel OP, and the non-display area NDA of the display device DD may mean the non-display area NDA of each of the display panel DP and the light converting panel OP.

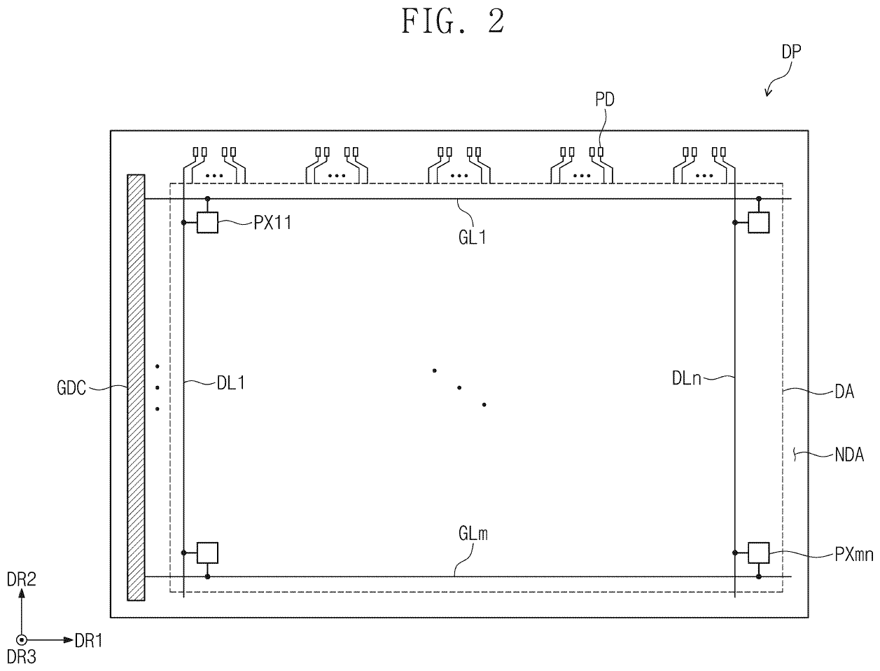

FIG. 2 is a plan view of the display panel DP according to some embodiments of the present disclosure.

FIG. 2 illustrates an arrangement relationship of signal lines GL1 to GLm and DL1 to DLn and pixels PX11 to PXmn on a plan view. The signal lines GL1 to GLm and DL1 to DLn may include a plurality of gate lines GL1 to GLm and a plurality of data lines DL1 to DLn.

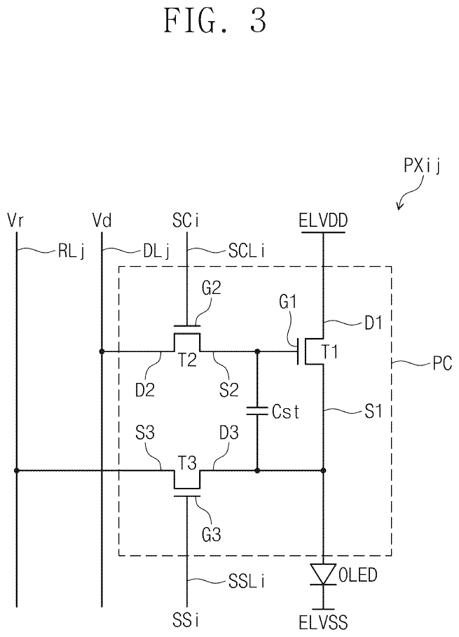

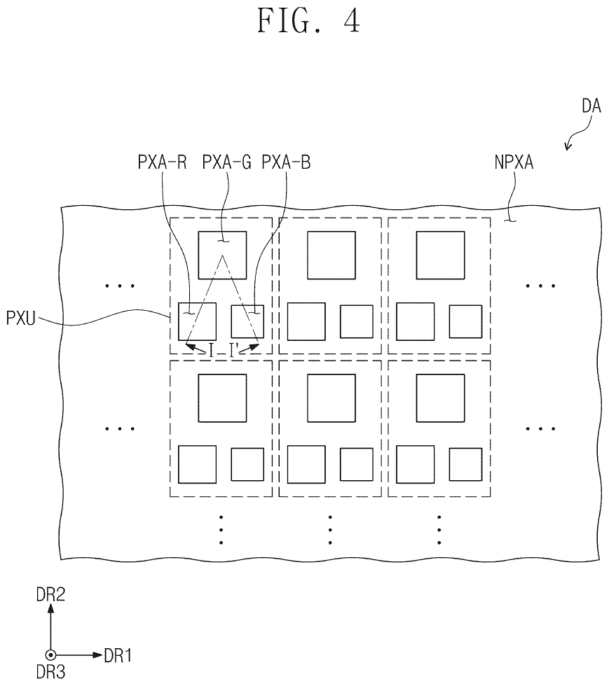

Each of the pixels PX11 to PXmn may be connected to a corresponding gate line among the plurality of gate lines GL1 to GLm and a corresponding data line among the plurality of data lines DL1 to DLn. Each of the pixels PX11 to PXmn may include a pixel driver circuit and a light emitting element. According to the configuration of the pixel driver circuit of the pixels PX11 to PXmn, more types of signal lines may be provided in the display panel DP. For example, each of the gate lines GL1 to GLm may include a corresponding scan line SCLi (see FIG. 3) and a corresponding sensing line SSLi (see FIG. 3).

A gate driver circuit GDC may be integrated in the display panel DP through an oxide semiconductor gate driver circuit (OSG) or amorphous silicon gate driver circuit (ASG) process. The gate driver circuit GDC connected to the gate lines GL1 to GLm may be located at one side of the non-display area NDA in the first direction DR1. Pads connected to ends of the plurality of data lines DL1 to DLn may be located at one side of the non-display area NDA in the second direction DR2.

FIG. 3 is an equivalent circuit diagram of a pixel PXij according to some embodiments of the present disclosure.

FIG. 3 illustrates, as an example, a pixel PXij connected to an i-th scan line SCLi, an i-th sensing line SSLi, a j-th data line DLj, and a j-th reference line RLj. The pixel PXij may include a pixel circuit PC and a light emitting element OLED connected to the pixel circuit PC. The pixel circuit PC may include a plurality of transistors T1, T2 and T3 and a capacitor Cst. The plurality of transistors T1, T2 and T3 may be formed through a low temperature polycrystaline silicon (LTPS) process or a low temperature polycrystalline oxide (LTPO) process. Hereinafter, the plurality of transistors T1, T2 and T3 are explained as n-type transistors, but at least one transistor may be implemented as a p-type transistor.

According to some embodiments, the pixel circuit PC including a first transistor T1, a second transistor T2, a third transistor T3, and the capacitor Cst is illustrated as an example, but the pixel circuit PC is not limited thereto. The first transistor T1 may be a driving transistor, the second transistor T2 may be a switching transistor, and the third transistor T3 may be a sensing transistor. The pixel circuit PC may further include an additional transistor or further include an additional capacitor.

The light emitting element OLED may be an organic light emitting element or inorganic light emitting element, which includes an anode (first electrode) and a cathode (second electrode). The anode of the light emitting element OLED may receive a first voltage ELVDD and the cathode of the light emitting element OLED may receive a second voltage ELVSS through the first transistor T1. The light emitting element OLED may receive the first voltage ELVDD and the second voltage ELVSS to emit light.

The first transistor T1 may include a drain D1 that receives the first voltage ELVDD, a source S1 connected to the anode of the light emitting element OLED, and a gate G1 connected to the capacitor Cst. The first transistor T1 may control driving current flowing through the light emitting element OLED from the first voltage ELVDD corresponding to a value of a voltage stored in the capacitor Cst.

The second transistor T2 may include a drain D2 connected to the j-th data line DLj, a source S2 connected to the capacitor Cst, and a gate G2 that receives the i-th first scan signal SCi. The j-th data line DLj may receive a data voltage Vd. The j-th data line DLj may receive a data voltage Vd. The second transistor T2 may transmit the data voltage Vd to the first transistor T1 in response to the i-th first scan signal SCi.

The third transistor T3 may include a source S3 connected to the j-th reference line RLj, a drain D3 connected to the anode of the light emitting element OLED, and a gate G3 that receives the i-th second scan signal SSi. The j-th reference line RLj may receive a reference voltage Vr. The third transistor T3 may initialize the capacitor Cst and the anode of the light emitting element OLED.

The capacitor Cst may store a voltage corresponding to a difference between a voltage transmitted from the second transistor T2 and the first voltage ELVDD. The capacitor Cst may be connected to the gate G1 of the first transistor T1 and the anode of the light emitting element OLED.

The pixel circuit PC according to some embodiments is not limited to having the specific components or structure as illustrated in FIG. 3. For example, according to some embodiments, the pixel circuit PC may have additional components or fewer components without departing from the spirit and scope of embodiments according to the present disclosure.

FIG. 4 is an enlarged plan view of a display area DA according to some embodiments of the present disclosure.

As illustrated in FIG. 4, unit pixels PXU may be aligned in each of the first direction DR1 and the second direction DR2. According to some embodiments, the unit pixels PXU may include a first pixel, a second pixel, and a third pixel, which emit light having different colors. The first pixel, the second pixel, and the third pixel may output red light, green light, and blue light, respectively. FIG. 4 illustrates a first pixel area PXA-R, a second pixel area PXA-G, and a third pixel area PXA-B, which are representative of the first pixel, the second pixel, and the third pixel, respectively. The first pixel area PXA-R may be an area in which light generated from the first pixel is provided to the outside, the second pixel area PXA-G may be an area in which light generated from the second pixel is provided to the outside, and the third pixel area PXA-B may be an area in which light generated from the third pixel is provided to the outside.

A peripheral area NPXA may be arranged to have a shape surrounding the first pixel area PXA-R, the second pixel area PXA-G, and the third pixel area PXA-B. The peripheral area NPXA may also be located between the first pixel area PXA-R, the second pixel area PXA-G, and the third pixel area PXA-B. The peripheral area NPXA may set a boundary of each of the first to third pixel areas PXA-R, PXA-G and PXA-B, and prevent mixture of colors among the first to third pixel areas PXA-R, PXA-G and PXA-B.

Referring to FIG. 4, the first pixel area PXA-R and the third pixel area PXA-B may be located in the same row, and the second pixel area PXA-G may be located in a different row from the first pixel area PXA-R and the third pixel area PXA-B. The second pixel area PXA-G may have the largest area, and the third pixel area PXA-B may have the smallest area. However, embodiments of the present disclosure are not limited thereto. According to some embodiments, each of the first pixel area PXA-R, the second pixel area PXA-G, and the third pixel area PXA-B is illustrated as having a substantially square shape. However, this shape is an example, and embodiments according to the present disclosure are not limited thereto.

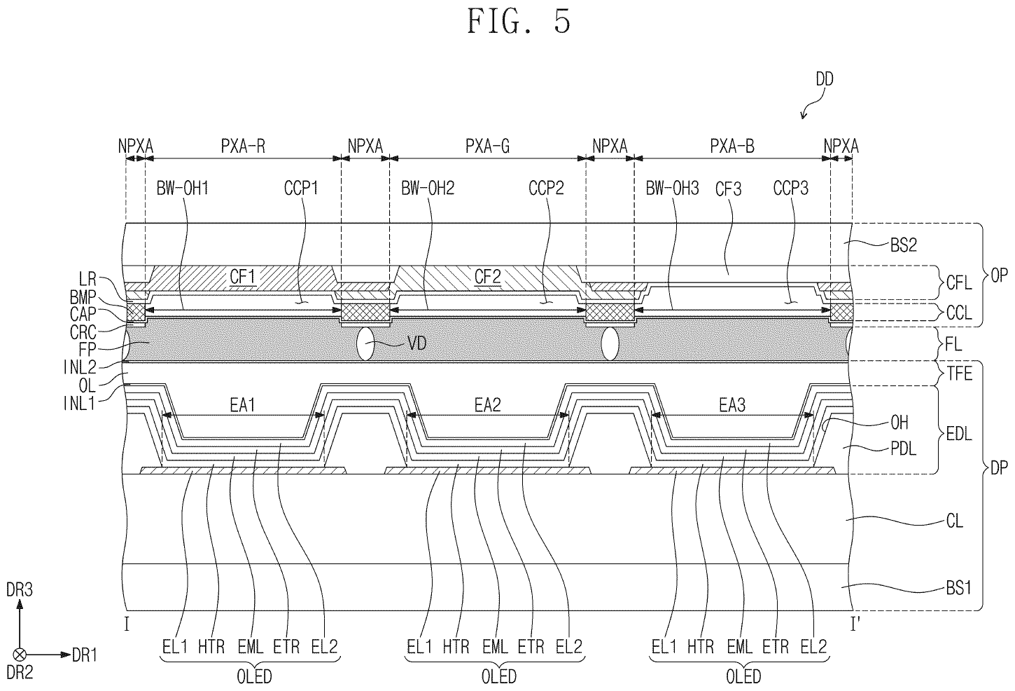

FIGS. 5 to 7 are cross-sectional views of portions of display devices DD, DD-a and DD-b according to some embodiments of the present disclosure, respectively.

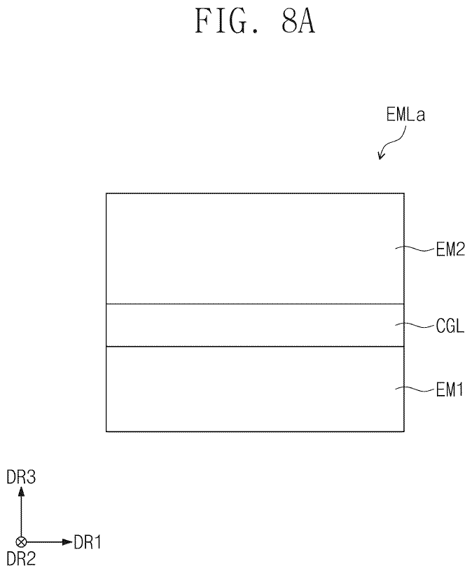

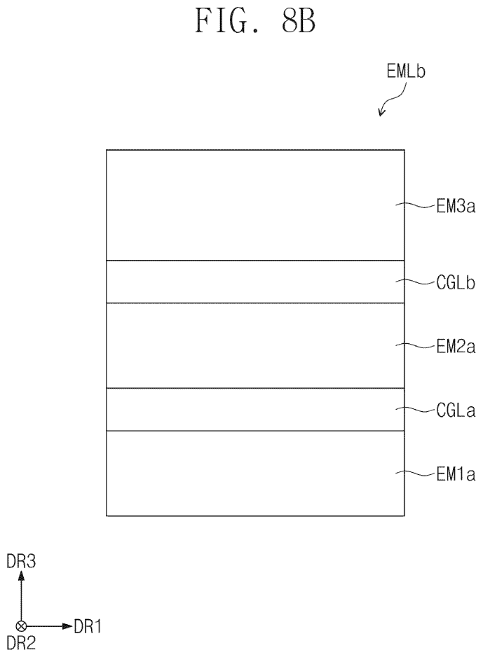

FIGS. 8A and 8B are cross-sectional views of emission layers EMLa and EMLb according to some embodiments of the present disclosure, respectively.

FIGS. 5 to 7 each illustrate a cross section corresponding to the line I-I′ in FIG. 4. These cross sections are examples, and embodiments according to the present disclosure are not limited thereto. FIGS. 5 to 7 each illustrate an example of a cross section of the first to third pixel areas PXA-R, PXA-G and PXA-B.

A display panel DP may include a first base layer BS1, a circuit layer CL, a light emitting element layer EDL, and a thin-film encapsulation layer TFE. The circuit layer CL may be located on the first base layer BS1. The light emitting element layer EDL may be located on the circuit layer CL. The thin-film encapsulation layer TFE may be located on the light emitting element layer EDL and seal the light emitting element layer EDL.

The first base layer BS1 may include a glass or synthetic resin film. A synthetic resin layer may include a thermosetting resin. In particular, the synthetic resin layer may be a polyimide-based resin layer, and the material thereof is not particularly limited. The synthetic resin layer may include at least one of an acrylic resin, a methacryl-based resin, polyisoprene, a vinyl-based resin, an epoxy-based resin, a urethane-based resin, a cellulose-based resin, a siloxane-based resin, a polyamide-based resin, or a perylene-based resin. In addition, the first base layer BS1 may include a glass substrate, a metal substrate, an organic/inorganic composite material substrate, or the like.

The circuit layer CL may be located on the first base layer BS1. The circuit layer CL may include an insulation layer, a semiconductor pattern, a conductive pattern, a signal line, and so on. The insulation layer, a semiconductor layer, and a conductive layer may be formed on the first base layer BS1 through coating, deposition or the like, and then, the insulation layer, the semiconductor layer, and the conductive layer may be selectively patterned by performing a photolithography process multiple times. Accordingly, the semiconductor pattern, the conductive pattern, and the signal line may be located on the circuit layer CL. The circuit layer CL may include a transistor, a buffer layer, and a plurality of insulation layers.

The light emitting element layer EDL may be located on the circuit layer CL, and include a light emitting element OLED and a pixel defining film PDL.

The light emitting element OLED may include a first electrode EL1, a second electrode EL2 facing the first electrode EL1, and an emission layer EML located between the first electrode EL1 and the second electrode EL2. The emission layer EML included in the light emitting element OLED may include, as a luminescent material, an organic luminescent material or a quantum dot. The light emitting element OLED may further include a hole transport region HTR and/or an electron transport region ETR. Meanwhile, according to some embodiments, the light emitting element OLED may further include a capping layer located at an upper portion of the second electrode EL2.

The pixel defining film PDL may be located on the circuit layer CL and cover a portion of the first electrode EL1. An emission opening portion OH may be defined in the pixel defining film PDL. The emission opening portion OH of the pixel defining film PDL exposes at least a portion of the first electrode EL1. Each of first to third emission areas EA1, EA2 and EA3 may be defined to correspond to the portion of the first electrode EL1, which is exposed by the emission opening portion OH of the pixel defining film PDL. The first emission area EA1, the second emission area EA2, and the third emission area EA3 may correspond to a first pixel area PXA-R, a second pixel area PXA-G, and a third pixel area PXA-B, respectively. An area excluding the first to third emission areas EA1, EA2 and EA3 may be defined as a non-emission area.

In the present disclosure, two components “corresponding to” each other means that the two components overlap each other when viewed in a thickness direction DR3 of each of the display devices DD, DD-a and DD-b (or when viewed on a plan view), and is not limited to having the same area. The first to third emission areas EA1, EA2 and EA3 may overlap the first to third pixel areas PXA-R, PXA-G and PXA-B, respectively. The areas of the first to third pixel areas PXA-R, PXA-G and PXA-B may be greater than the areas of the first to third emission areas EA1, EA2 and EA3, respectively, which are divided by the pixel defining film PDL, when viewed on a plan view. However, this is just an example, and embodiments according to the present disclosure are not limited thereto. The areas of the first to third pixel areas PXA-R, PXA-G and PXA-B may be substantially the same as the areas of the first to third emission areas EA1, EA2 and EA3, respectively, which are divided by the pixel defining film PDL.

The first electrode EL1 may be located on the circuit layer CL. The first electrode EL1 may be an anode or a cathode. The first electrode EL1 may also be a pixel electrode. The first electrode EL1 may be a transmissive electrode, a transflective electrode, or a reflective electrode.

The hole transport region HTR may be located on the first electrode EL1. The hole transport region HTR may be located, in common, in the first to third emission areas EA1, EA2 and EA3 and the non-emission area. A common layer like the hole transport region HTR may be arranged to overlap the plurality of unit pixels PXU in the display area DA illustrated in FIG. 4. However, embodiments according to the present disclosure are not limited thereto, and the hole transport region HTR may be arranged to be separated to correspond to each of the first to third emission areas EA1, EA2 and EA3. The hole transport region HTR may include at least one of a hole transport layer, a hole injection layer, or an electron blocking layer.

The emission layer EML may be located on the hole transport region HTR. The emission layer EML may be located, in common, in the first to third emission areas EA1, EA2 and EA3 and the non-emission area. The emission layer EML may be arranged to overlap the entirety of the hole transport region HTR and the electron transport region ETR. However, embodiments according to the present disclosure are not limited thereto, and the emission layer EML may be located within the emission opening portion OH according to some embodiments. That is, the emission layer EML may be arranged to be separated to correspond to each of the first to third emission areas EA1, EA2 and EA3 divided by the pixel defining film PDL.

The emission layer EML may generate source light. According to some embodiments, the emission layer EML may emit blue light. In the display devices DD, DD-a and DD-b according to some embodiments, the blue light may be the source light. Meanwhile, when the emission layer EML is arranged to be separated to correspond to each of the first to third emission areas EA1, EA2 and EA3, the emission layers EML may all emit the blue light, or may emit light having different wavelength regions in the first to third emission areas EA1, EA2 and EA3, respectively.

The emission layer EML may have a single layer made of a single material, or a single layer made of a plurality of different materials, or may have a multilayer structure having a plurality of layers made of a plurality of different materials. The emission layer EML may include a fluorescent or phosphorescent material. In a light emitting element according to some embodiments, the emission layer EML may include a luminescent material such as an organic luminescent material, an organometallic complex, or a quantum dot.

FIGS. 8A and 8B are cross-sectional views illustrating examples of a case in which the foregoing emission layer EML (see FIGS. 5 to 7) has a multilayer structure.

Referring to FIG. 8A, an emission layer EMLa may include a first emission layer EM1, a charge generation layer CGL, and a second emission layer EM2 that are stacked in sequence in the third direction DR3. The first emission layer EM1 and the second emission layer EM2 may emit light having different colors from each other. For example, the first emission layer EM1 may emit blue light, and the second emission layer EM2 may emit green light.

The charge generation layer CGL may be located between the first emission layer EM1 and the second emission layer EM2. The charge generation layer CGL may supply electrons or holes to each of the first emission layer EM1 and the second emission layer EM2 to relatively improve emission efficiency.

Referring to FIG. 8B, an emission layer EMLb may include a first emission layer EM1a, a first charge generation layer CGLa, a second emission layer EM2a, a second charge generation layer CGLb, and a third emission layer EM3a that are stacked in sequence in the third direction DR3.

One of the first emission layer EM1a, the second emission layer EM2a, and the third emission layer EM3a may emit light having a different color from the other two. For example, the first emission layer EM1a and the third emission layer EM3a may emit light having the same color, and the second emission layer EM2a may emit light having a different color from the light generated in the first emission layer EM1a. For example, the first emission layer EM1a and the third emission layer EM3a may emit blue light, and the second emission layer EM2a may emit green light.

The first charge generation layer CGLa may be located between the first emission layer EM1a and the second emission layer EM2a. The second charge generation layer CGLb may be located between the second emission layer EM2a and the third emission layer EM3a. The first charge generation layer CGLa may supply electrons or holes to each of the first emission layer EM1a and the second emission layer EM2a to relatively improve the emission efficiency. In addition, the second charge generation layer CGLb may supply electrons or holes to each of the second emission layer EM2a and the third emission layer EM3a to relatively improve the emission efficiency.

Referring to FIGS. 5 to 7, the electron transport region ETR may be located on the emission layer EML. The electron transport region ETR may include at least one of an electron injection layer, an electron transport layer, or a hole blocking layer. The electron transport region ETR may be arranged as a common layer so as to overlap the entirety of the first to third emission areas EA1, EA2 and EA3 and the pixel defining film PDL. However, embodiments according to the present disclosure are not limited thereto, and the electron transport region ETR may be arranged to be separated to correspond to each of the first to third emission areas EA1, EA2 and EA3.

The second electrode EL2 may be located on the electron transport region ETR. The second electrode EL2 may be a common electrode. The second electrode EL2 may be a cathode or an anode, but embodiments according to the present disclosure are not limited thereto. For example, the second electrode EL2 may be a cathode when the first electrode EL1 is an anode, and the second electrode EL2 may be an anode when the first electrode EL1 is a cathode. The second electrode EL2 may be a transmissive electrode, a transflective electrode, or a reflective electrode.

The thin-film encapsulation layer TFE may be located on the second electrode EL2. Alternatively, when the light emitting element OLED includes a capping layer, the thin-film encapsulation layer TFE may be located on the capping layer. The thin-film encapsulation layer TFE may serve to protect the light emitting element layer EDL from moisture and oxygen, and prevent foreign matters such as dust, from being introduced into the light emitting element layer EDL.

The thin-film encapsulation layer TFE may include at least one inorganic film INL1 or INL2. The inorganic film INL1 or INL2 may include at least one of a silicon nitride, a silicon oxynitride, a silicon oxide, a titanium oxide, or an aluminum oxide. The thin-film encapsulation layer TFE may include at least one organic film OL. The organic film OL may include an organic polymeric material formed from an acrylate-based resin or the like. However, these materials are examples, and embodiments according to the present disclosure are not limited thereto.

The light converting panel OP may be located on the display panel DP. The light converting panel OP may include a second base layer BS2, a color filter layer CFL, a low refractive layer LR, a light control layer CCL, and a capping layer CAP. The color filter layer CFL may be located below the second base layer BS2. The low refractive layer LR may be located below the color filter layer CFL. The light control layer CCL may be located below the low refractive layer LR. The capping layer CAP may be located below the light control layer CCL.

The second base layer BS2 may be a member that provides a base surface on which the color filter layer CFL and the like, are located. The second base layer BS2 may include a glass or synthetic resin film. The synthetic resin film may include a thermosetting resin. In particular, the synthetic resin layer may be a polyimide-based resin layer, and the material thereof is not particularly limited. The synthetic resin layer may include at least one of an acrylic resin, a methacryl-based resin, polyisoprene, a vinyl-based resin, an epoxy-based resin, a urethane-based resin, a cellulose-based resin, a siloxane-based resin, a polyamide-based resin, or a perylene-based resin. In addition, the second base layer BS2 may include a glass substrate, a metal substrate, an organic/inorganic composite material substrate, or the like.

The color filter layer CFL is located below the second base layer BS2. The color filter layer CFL may include color filters CF1, CF2 and CF3. The color filter layer CFL may include a first color filter CF1 through which light having a second color passes, a second color filter CF2 through which light having a third color passes, and a third color filter CF3 through which light having a first color passes. For example, the first color filter CF1 may be a red color filter, the second color filter CF2 may be a green color filter, and the third color filter CF3 may be a blue color filter. Meanwhile, the first color filter CF1 and the second color filter CF2 may be yellow color filters. The first color filter CF1 and the second color filter CF2 may be provided as one body without being separated from each other.

The first color filter CF1 may allow only light within a partial wavelength range of the light having the second color, i.e., light in a centroid wavelength range, to pass therethrough to increase the color purity. The second color filter CF2 may allow only light within a partial wavelength range of the light having the third color, i.e., light in a centroid wavelength range, to pass therethrough to increase the color purity. The third color filter CF3 may allow only light within a partial wavelength range of the light having the first color, i.e., light in a centroid wavelength range, to pass therethrough to increase the color purity.

Each of the color filters CF1, CF2 and CF3 may include a polymer photosensitive resin and a pigment or a dye. The first color filter CF1 may include a red pigment or dye, the second color filter CF2 may include a green pigment or dye, and the third color filter CF3 may include a blue pigment or dye. Meanwhile, embodiments according to the present disclosure are not limited thereto, and the third color filter CF3 may not include a pigment or dye. The third color filter CF3 may include a polymer photosensitive resin but not include a pigment or a dye. The third color filter CF3 may be transparent. The third color filter CF3 may include a transparent photosensitive resin.

The first to third color filters CF1, CF2 and CF3 may be arranged to correspond to the first pixel area PXA-R, the second pixel area PXA-G, and the third pixel area PXA-B, respectively. In addition, the first to third color filter layers CF1, CF2 and CF3 may be arranged to correspond to first to third light controllers CCP1, CCP2 and CCP3, respectively.

The plurality of color filters CF1, CF2 and CF3, which allow light having different colors to pass therethrough, may be arranged to overlap each other at a position corresponding to the peripheral area NPXA located between the pixel areas PXA-R, PXA-G and PXA-B. The plurality of color filters CF1, CF2 and CF3 may be arranged to overlap each other in the third direction DR3 that is the thickness direction. An area on which the plurality of color filters CF1, CF2 and CF3 are arranged to overlap each other may define a boundary between the adjacent emission areas PXA-R, PXA-G and PXA-B.

The area of a portion at which only the first color filter CF1 is located may be less than the area of the first light controller CCP1 when viewed on a plan view. The area of a portion at which only the second color filter CF2 is located may be less than the area of the second light controller CCP2 when viewed on a plan view. The area of a portion at which only the third color filter CF3 is located may be less than the area of the third light controller CCP3 when viewed on a plan view. Thus, the area of the first pixel area PXA-R may be less than the area of the first light controller CCP1, the area of the second pixel area PXA-G may be less than the area of the second light controller CCP2, and the area of the third pixel area PXA-B may be less than the area of the third light controller CCP3.

Unlike that illustrated, the color filter layer CFL may include a light blocking part that defines a boundary between the adjacent color filters CF1, CF2 and CF3. The light blocking part may be provided as a blue color filter, or may include an organic light blocking material or inorganic light blocking material, which includes a black pigment or a black dye.

The low refractive layer LR may be located below the color filter layer CFL. The low refractive layer LR may be located on the light control layer CCL. The low refractive layer LR may also be located between the light control layer CCL and the color filter layer CFL to relatively improve light extraction efficiency or perform a function of an optical functional layer, such as preventing reflected light from entering the light control layer CCL. The low refractive layer LR may be a layer having a lower refractive index than an adjacent layer. For example, the refractive index of the low refractive layer LR may be about 1.45 or less.

The low refractive layer LR may include at least one inorganic layer. For example, the low refractive layer LR may be made by including a silicon nitride, an aluminum nitride, a zirconium nitride, a titanium nitride, a hafnium nitride, a tantalum nitride, a silicon oxide, an aluminum oxide, a titanium oxide, a tin oxide, a cerium oxide, or a silicon oxynitride, or a metal thin film having light transmittance or the like. However, embodiments according to the present disclosure are not limited thereto, and the low refractive layer LR may include an organic film. For example, the low refractive layer LR may be made by including a polymer resin, an inorganic particle, and the like.

The light control layer CCL may be located below the low refractive layer LR. The light control layer CCL may include a division pattern BMP and the light controllers CCP1, CCP2 and CCP3. The division pattern BMP may overlap the peripheral area NPXA on a plan view. The light controllers CCP1, CCP2 and CCP3 included in the light control layer CCL may be arranged to be spaced apart from each other. The light controllers CCP1, CCP2 and CCP3 may be arranged to be spaced apart from each other by the division pattern BMP. The light controllers CCP1, CCP2 and CCP3 may be located in opening portions BW-OH1, BW-OH2 and BW-OH3, respectively, which are defined in the division pattern BMP. However, embodiments according to the present disclosure are not limited thereto, and an edge of each of the light controllers CCP1, CCP2 and CCP3 may have at least a portion overlapping the division pattern BMP.

The division pattern BMP may include a material having a transmittance less than or equal to a value (e.g., a set or predetermined value). For example, the division pattern BMP may include a light blocking material, and may include a black coloring agent. The division pattern BMP may include a black dye or black pigment mixed in a base resin. In the division pattern BMP, for example, the black coloring agent may include a carbon black, or include a metal such as chrome, or an oxide thereof. The division pattern BMP may include, for example, at least one of propylene glycol methyl ether acetate, 3-methoxy-n-butyl acetate, acrylate monomer, acrylic monomer, organic pigment, or acrylate ester.

Each of the light controllers CCP1, CCP2 and CCP3 may be a portion that converts a wavelength of the source light supplied from the light emitting element layer EDL or allows the light to pass therethrough without converting the wavelength of the supplied source light. The light controllers CCP1, CCP2 and CCP3 may be formed through an inkjet process. A liquid ink composition may be supplied into each of the opening portions BW-OH1, BW-OH2 and BW-OH3, and the supplied liquid ink composition may be polymerized through a thermal curing process or an optical curing process to form the light controllers CCP1, CCP2 and CCP3. That is, the opening portions BW-OH1, BW-OH2 and BW-OH3 may have shapes corresponding to shapes of the light controllers CCP1, CCP2 and CCP3, respectively.

The light control layer CCL may include a first light controller CCP1 including a first quantum dot, which converts the light having the first color supplied from the light emitting element OLED into the light having the second color, a second light controller CCP2 including a second quantum dot, which converts the light having the first color into the light having the third color, and a third light controller CCP3 which allows the light having the first color passes therethrough. The first light controller CCP1 may provide red light that is the light having the second color, and the second light controller CCP2 may provide green light that is the light having the first color. The third light controller CCP3 may provide blue light by allowing the blue light, which is the light having the first color supplied from the light emitting element OLED, to pass therethrough. For example, the first quantum dot may be a red quantum dot, and the second quantum dot may be a green quantum dot.

The quantum dot means a crystal of a semiconductor compound. As an energy band gap is adjustable by adjusting the size of the quantum dot or adjusting an element ratio in the quantum dot, light having various wavelength ranges may be obtained. For example, the quantum dot may have a diameter of about 1 nm to about 10 nm. Thus, a light emitting element that emits light having several wavelengths may be achieved by using quantum dots having different sizes or using quantum dots having different element ratios in quantum dots. Specifically, the quantum dots may be implemented to emit red, green or blue light. The quantum dots may also be configured to combine light having various colors to emit white light.

The quantum dots may be synthesized through a wet chemical process, metal organic chemical vapor deposition, molecular beam epitaxy, or like operations. The wet chemical process is a method of mixing an organic solution and a precursor material and then growing a quantum dot particle crystal. When the crystal is grown, the organic solvent may be naturally coordinated on a surface of the quantum dot crystal to serve as a dispersant, and may control the growth of the crystal. Thus, in the wet chemical process, the growth of quantum dot particles may be controlled through a process that is easier and is lower in manufacturing costs than a vapor deposition process such as the metal organic chemical vapor deposition (MOCVD) or the molecular beam epitaxy (MBE).

The quantum dot may have a single structure or a dual core-shell structure in which the concentration of each element included in the quantum dot is uniform. For example, a material included in a core and a material included in a shell may be different from each other. The shell of the quantum dot may serve as a protective layer for preventing the chemical deformation of the core to maintain semiconductor properties, and/or as a charging layer for imparting electrophoresis properties to the quantum dot. The shell may be a single-layer shell or a multilayer shell. The core/shell structure may have a concentration gradient in which the concentration of elements present in the shell gradually decreases toward the core.

The core of the quantum dot may be selected from a Group II-VI compound, a Group III-VI compound, a Group I-III-VI compound, a Group III-V compound, a Group III-II-V compound, a Group IV-VI compound, a Group IV element, a Group IV compound, and a combination thereof.

The Group II-VI compound may be selected from the group consisting of a binary compound selected from the group consisting of CdSe, CdTe, CdS, ZnS, ZnSe, ZnTe, ZnO, HgS, HgSe, HgTe, MgSe, MgS, and a mixture thereof, a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof, and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, and a mixture thereof.

The Group III-VI compound may include a binary compound such as In₂S₃ and In₂Se₃, a ternary compound such as InGaS₃ and InGaSe₃, or any combination thereof.

The Group I-III-VI compound may be selected from a ternary compound selected from the group consisting of AgInS, AgInS₂, CuInS, CuInS₂, AgGaS₂, CuGaS₂, CuGaO₂, AgGaO₂, AgAlO₂, and a mixture thereof, or a quaternary compound such as AgInGaS₂ and CuInGaS₂.

The Group III-V compound may be selected from the group consisting of a binary compound selected from the group consisting of GaN, GaP, GaAs, GaSb, AlN, AlP, AlAs, AlSb, InN, InP, InAs, InSb, and a mixture thereof, a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and a mixture thereof, and a quaternary compound selected from the group consisting of GaAlNP, GaAlNAs, GaAlNSb, GaAlPAs, GaAlPSb, GalnNP, GalnNAs, GalnNSb, GalnPAs, GalnPSb, InAlNP, InAlNAs, InAlNSb, InAlPAs, InAlPSb, and a mixture thereof. Meanwhile, the Group III-V compound may further include a Group II metal. For example, the Group III-II-V compound may be selected from InZnP or the like.

The Group IV-VI compound may be selected from the group consisting of a binary compound selected from the group consisting of SnS, SnSe, SnTe, PbS, PbSe, PbTe, and a mixture thereof, a ternary compound selected from the group consisting of SnSeS, SnSeTe, SnSTe, PbSeS, PbSeTe, PbSTe, SnPbS, SnPbSe, SnPbTe, and a mixture thereof, and a quaternary compound selected from the group consisting of SnPbSSe, SnPbSeTe, SnPbSTe, and a mixture thereof. The Group IV element may be selected from the group consisting of Si, Ge, and a mixture thereof. The Group IV compound may be a binary compound selected from the group consisting of SiC, SiGe, and a mixture thereof.

The Group IV element or compound may include a single-element compound such as Si or Ge, a binary compound such as SiC or SiGe, or any combination thereof.

Here, each of elements included in a multi-element compound such as the binary compound, the ternary compound, and the quaternary compound, may be present in a particle with a uniform concentration or non-uniform concentration. That is, each of the foregoing chemical formulas mean types of the elements included in the compound, and an element ratio in the compound may be different. For example, AgInGaS₂ may mean AgInₓGa₁₋ₓS₂ (x is a real number of from about 1 to about 1).

The shell of the quantum dot may include a metal oxide, a non-metal oxide, a semiconductor compound, or a combination thereof.

For example, the metal or non-metal oxide may include a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, and NiO, or a ternary compound such as MgAl₂O₄, CoFe₂O₄, NiFe₂O₄, and CoMn₂O₄, but embodiments according to the present disclosure are not limited thereto.

In addition, examples of the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, and AlSb, but embodiments according to the present disclosure are not limited thereto.

The quantum dot may have a full width of half maximum (FWHM) in an emission wavelength spectrum of about 45 nm or less, preferably about 40 nm or less, more preferably about 30 nm or less, and, in this range, the color purity or color reproducibility may be relatively improved. In addition, as light emitted through this quantum dot is emitted in all directions, a wide viewing angle may be relatively improved.

The shape of the quantum dot is one generally used in the relevant art and is not particularly limited. However, more specifically, the quantum dots may be used which are spherical, pyramidal, multi-armed, or in the form of a cubic nanoparticle, a nanotube, a nanowire, a nanofiber, a nanoplate particle, or the like.

As described above, the color of light emitted by the quantum dot may be adjusted according to the particle size and accordingly, the quantum dots may have various emission colors such as blue, red, and green. As the particle size of the quantum dot is smaller, the quantum dot may emit light having a shorter-wavelength range. For example, in quantum dots having the same core, the particle size of the quantum dot emitting green light may be less than the particle size of the quantum dot emitting red light. In addition, in quantum dots having the same core, the particle size of the quantum dot emitting blue light may be less than the particle size of the quantum dot emitting green light. However, embodiments according to the present disclosure are not limited thereto, and, also in the quantum dots having the same core, the particle size may be adjusted according to a material forming the shell, a shell thickness, and the like. Meanwhile, when quantum dots have various emission colors such as blue, red, and green, the quantum dots having different emission colors may be different from each other in terms of the core materials.

The light control layer CCL may further include a scatterer. The first light controller CCP1 may include a first quantum dot and a scatterer, the second light controller CCP2 may include a second quantum dot and a scatterer, and the third light controller CCP3 may include a scatterer but not a quantum dot.

The scatterer may be an inorganic particle. For example, the scatterer SP may include at least one of TiO₂, ZnO, Al₂O₃, SiO₂, or hollow silica. The scatterer SP may include any one of TiO₂, ZnO, Al₂O₃, SiO₂, and hollow silica, or may be a mixture of two or more materials selected from TiO₂, ZnO, Al₂O₃, SiO₂, and hollow silica. Each of the first light controller CCP1, the second light controller CCP2, and the third light controller CCP3 may further include a base resin in which the quantum dot and the scatterer are dispersed. According to some embodiments, the first light controller CCP1 may include first quantum dots and scatterers, which are dispersed in the base resin, the second light controller CCP2 may include second quantum dots and scatterers, which are dispersed in the base resin, and the third light controller CCP3 may include scatterers dispersed in the base resin.

The base resin is a medium, in which the quantum dots and the scatterers are dispersed, and may be composed of various resin compositions that may be generally referred to as binders. For example, the base resin may be an acrylic resin, a urethane-based resin, a silicon-based resin, an epoxy-based resin, or the like. The base resin may be a transparent resin.

The capping layer CAP may be located below the light control layer CCL. The capping layer CAP may serve to prevent moisture and/or oxygen from being permeated. The capping layer CAP may be located below the light controllers CCP1, CCP2 and CCP3 to block the light controllers CCP1, CCP2 and CCP3 from being exposed to moisture/oxygen. In addition, the capping layer CAP may cover not only the light controllers CCP1, CCP2 and CCP3 but also the division pattern BMP.

The capping layer CAP may include at least one inorganic layer. That is, the capping layer CAP may include an inorganic material. For example, the capping layer CAP may include a silicon nitride, an aluminum nitride, a zirconium nitride, a titanium nitride, a hafnium nitride, a tantalum nitride, a silicon oxide, an aluminum oxide, a titanium oxide, a tin oxide, a cerium oxide, and a silicon oxynitride, or a metal thin film having light transmittance or the like. However, embodiments according to the present disclosure are not limited thereto. Meanwhile, the capping layer CAP may further include an organic film. The capping layer CAP may be constituted by a single layer or a plurality of layers.

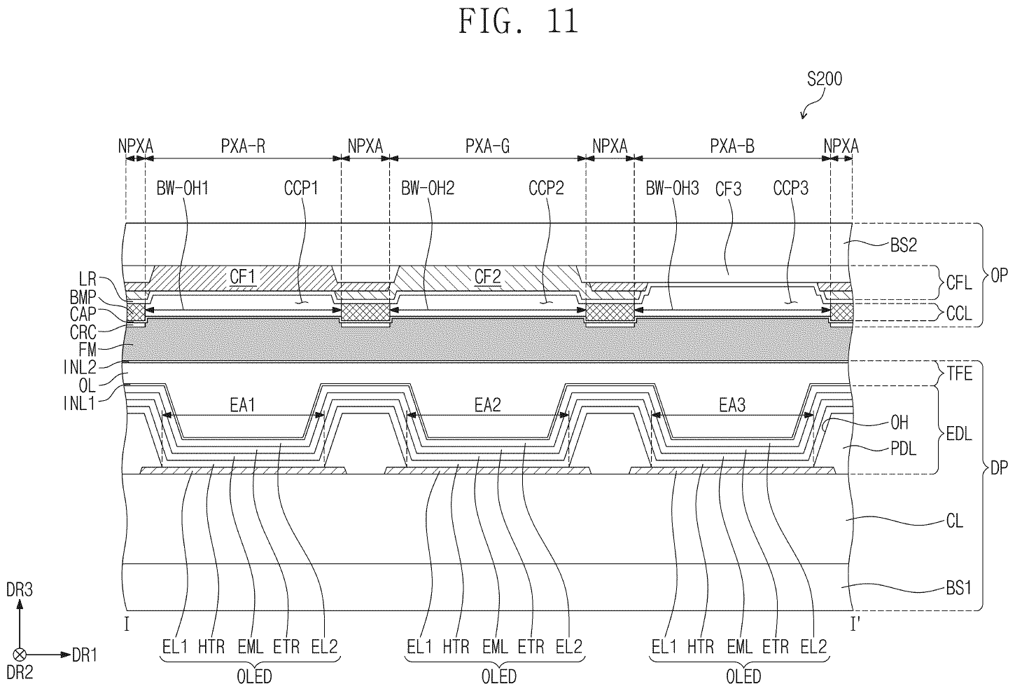

The light converting panel OP according to some embodiments of the present disclosure further includes each of cure control layers CRC, CRC-a and CRC-b. The cure control layers CRC, CRC-a and CRC-b may mean layers that serve to adjust curing of a filling material FM (see FIG. 11) to be described later. For example, the cure control layers CRC, CRC-a and CRC-b may chemically suppress initiation of curing to retard curing of a peripheral portion, or may physically suppress a flow of a material to adjust the curing. Alternatively, the curing may be chemically and physically adjusted at the same time. This content will be described in detail later.

Each of the cure control layers CRC, CRC-a and CRC-b may be located below the division pattern BMP. Although FIGS. 5 to 7 illustrate that each of the cure control layers CRC, CRC-a and CRC-b is located directly below the capping layer CAP located below the division pattern BMP, the capping layer CAP may be omitted. When the capping layer CAP is omitted, each of the cure control layers CRC, CRC-a and CRC-b may be located directly below the division pattern BMP.

Each of the cure control layers CRC, CRC-a and CRC-b may be located to overlap the division pattern BMP on a plan view. Each of the cure control layers CRC, CRC-a and CRC-b may be located between the first to third pixel areas PXA-R, PXA-G and PXA-B on a plan view. Each of the cure control layers CRC, CRC-a and CRC-b may have an area that is substantially the same as an area of the division pattern BMP. However, embodiments of the present disclosure are not limited thereto, and the area of each of the cure control layers CRC, CRC-a and CRC-b may also be less than the area of the division pattern BMP.

Each of the cure control layers CRC, CRC-a and CRC-b may be located at the lowest side of the light converting panel OP and between the first to third pixel areas PXA-R, PXA-G and PXA-B on a plan view, so as to adjust the curing of the filling material FM (see FIG. 11) that is arranged to couple the display panel DP and the light converting panel OP to each other. As the curing of the filling material FM (see FIG. 11) is adjusted, each of voids VD, VD-a and VD-b may be provided between the first to third pixel areas PXA-R, PXA-G and PXA-B in a filling layer FL on a plan view. Each of the voids VD, VD-a and VD-b may be vacuumed or filled with air to have low-refractive properties compared to the peripheral portion, and accordingly, may induce total reflection of light at a boundary of each of the voids VD, VD-a and VD-b. The voids VD, VD-a and VD-b will be described in detail later.

The cure control layers CRC, CRC-a and CRC-b may include organic matters. For example, the cure control layers CRC, CRC-a and CRC-b may include photosensitive polyimide (PSPI). However, the material of the cure control layers CRC, CRC-a and CRC-b is not limited thereto.

Referring to FIG. 5, the cure control layer CRC may include a cure retardant material. The cure retardant material may mean a material that suppresses initiation of curing of the filling material FM (see FIG. 11) to be described later so as to retard the curing of the filling material. As the cure control layer CRC includes a cure retardant material, initiation of curing of the filling material at a position adjacent to the cure control layer CRC may be suppressed so that the curing of the filling material is retarded compared to the filling material at a position that is not adjacent to the cure control layer CRC.

For example, when the filling material is an epoxy-based material, the cure retardant material may include an amine group (NH₃). The amine group may first react with H⁺ ions, which are ionic initiators of the epoxy-based filling material, and moisture, which remains in the bonding of the display panel DP and the light converting panel OP to each other, so that the curing of the filling material is retarded. In addition, when the filling material is a silicon-based material, the cure retardant material may include a silane group (SH₄). Due to a Si—H bond of the silane group, a vinyl group of the silicon-based filling material may be open to retard the curing of the filling material. However, the cure retardant material according to some embodiments of the present disclosure is not limited thereto, and a material may be applied as long as the material is capable of suppressing initiation of curing of a material, which is used as the filling material FM (see FIG. 11), to retard the curing thereof.

As the cure control layer CRC includes the cure retardant material, the cure control layer CRC may adjust the curing of the filling material FM (see FIG. 11) formed in order to couple the display panel DP and the light converting panel OP to each other. When the filling material FM (see FIG. 11) is cured to contract, the retarded rate at the peripheral portion of the cure control layer CRC may be relatively low. That is, the curing may be chemically adjusted.

Accordingly, the void VD may be provided between the first to third pixel areas PXA-R, PXA-G and PXA-B in the filling layer FL on a plan view. The void VD may be vacuumed or filled with air to have low-refractive properties compared to the peripheral portion, and accordingly, may induce total reflection of light at a boundary of the void VD.

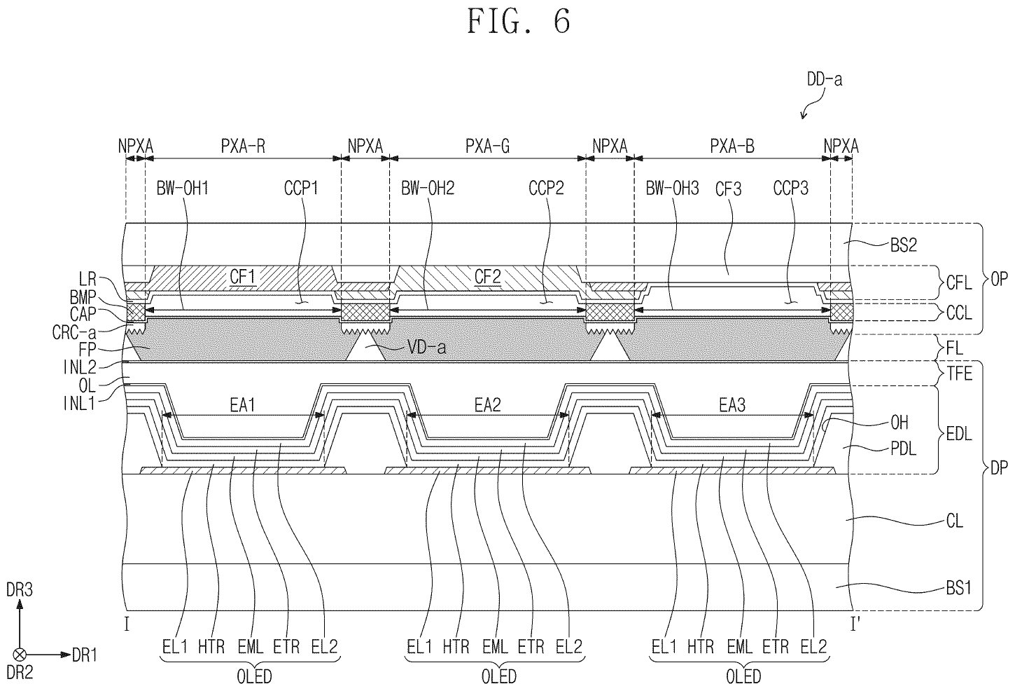

Referring to FIG. 6, the cure control layer CRC-a may include an unevenness. The cure control layer CRC-a may have a top surface adjacent to the division pattern BMP, and a bottom surface adjacent to the filling layer FL. The cure control layer CRC-a may include the unevenness on the bottom surface.

As the cure control layer CRC-a includes the unevenness on the bottom surface, the cure control layer CRC-a may adjust the curing of the filling material FM (see FIG. 11—) formed in order to couple the display panel DP and the light converting panel OP to each other. When the filling material FM (see FIG. 11) is cured to contract, a flow rate of the filling material at a peripheral portion of the unevenness may be lower than a flow rate at an opposite side. That is, the curing may be physically adjusted.

Accordingly, the void VD-a may be provided between the first to third pixel areas PXA-R, PXA-G and PXA-B in the filling layer FL on a plan view. The void VD-a may be vacuumed or filled with air to have low-refractive properties compared to the peripheral portion, and accordingly, may induce total reflection of light at a boundary of the void VD-a.

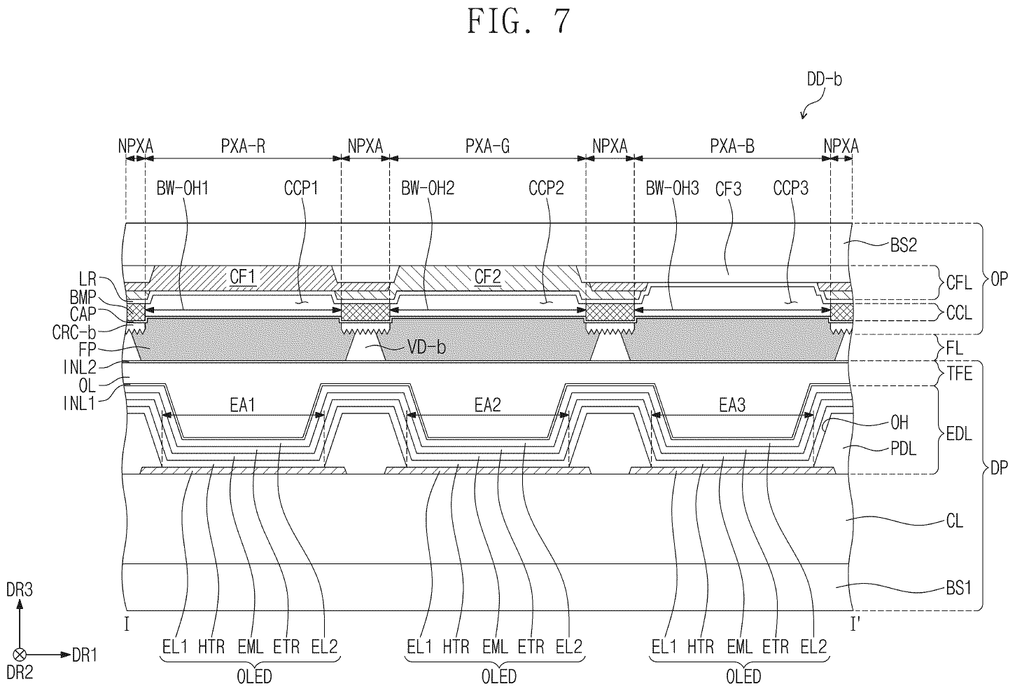

Referring to FIG. 7, the cure control layer CRC-b may include the cure retardant material and also include the unevenness on the bottom surface. The cure control layer CRC-b may chemically adjust the curing as described above with reference to FIG. 5 and physically adjust the curing at the same time as described above with reference to FIG. 6.

Each of the display devices DD, DD-a and DD-b includes the filling layer FL located between the display panel DP and the light converting panel OP. The filling layer FL may be filled between the display panel DP and the light converting panel OP. The filling layer FL may function as a buffer between the display panel DP and the light converting panel OP. The filling layer FL may perform an impact absorption function or the like, and may increase the rigidity of the display devices DD, DD-a and DD-b.

The source light supplied from the display panel DP may arrive at the light converting panel OP through the filling layer FL. The light emitting element OLED of the display panel DP may emit light in all directions. Thus, when the light emitted from the light emitting element OLED travels toward the division pattern BMP, which is located between the first to third pixel areas PXA-R, PXA-G and PXA-B, or the other adjacent pixel areas PXA-R, PXA-G and PXA-B, side losses may occur. That is, the light extraction efficiency and the color reproducibility of the light emitted to the outside of the display devices DD, DD-a and DD-b may decrease.

Referring to FIGS. 5 to 7, the filling layer FL according to some embodiments of the present disclosure may include a filled portion FP and each of the voids VD, VD-a and VD-b.

The filled portion FP may overlap the first to third pixel areas PXA-R, PXA-G and PXA-B, and overlap the plurality of light controllers CCP1, CCP2 and CCP3 on a plan view. Here, the term “overlapping” does not mean that the area of the filled portion FP is the same as the area of each of the first to third pixel areas PXA-R, PXA-G and PXA-B or the area of each of the plurality of light controllers CCP1, CCP2 and CCP3 on a plan view, and may be intended to indicate a positional relationship in which the filled portion FP is located on a plan view.

The filled portion FP may be formed from a filling resin including a polymer resin. For example, the filled portion FP may include a resin including an epoxy-based resin, a silicon-based resin, an acrylic resin, or the like.

The filling layer FL may include each of the voids VD, VD-a and VD-b at a position at which the filling layer FL overlaps the division pattern BMP on a plan view. Here, the term “overlapping” does not mean that the area of each of the voids VD, VD-a and VD-b is the same as the area of the division pattern BMP on a plan view, and may be intended to indicate a positional relationship in which each of the voids VD, VD-a and VD-b is located on a plan view. That is, each of the voids VD, VD-a and VD-b may be located in the peripheral area NPXA between the first to third pixel areas PXA-R, PXA-G and PXA-B on a plan view.

The voids VD, VD-a and VD-b may mean empty spaces, each of which is a partial space left without being filled with the filling material FM to be described later as the filling layer FL is cured to contract. The void VD may be vacuumed or filled with air to have low-refractive properties compared to the peripheral portion. For example, the void VD may have a refractive index of about 1.0, and the filled portion FP that is the peripheral portion may have a refractive index of about 1.6.

Accordingly, light, which travels toward a side surface, of the light emitted from the display panel DP may be totally reflected at a boundary of each of the voids VD, VD-a and VD-b to travel toward the light converting panel OP. That is, the side losses may be reduced to relatively improve the light extraction efficiency of the display devices DD, DD-a and DD-b.

Referring to FIG. 5, the shape of the void VD in the case in which the cure control layer CRC includes a cure retardant material is illustrated as an example. As the cure control layer CRC includes a cure retardant material, initiation of the curing of the filling material, which is located between the first to third pixel areas PXA-R, PXA-G and PXA-B, at a position adjacent to the cure control layer CRC may be suppressed. That is, the curing of the filling material may be retarded compared to the filling material, which is located in the first to third pixel areas PXA-R, PXA-G and PXA-B, at a position that is not adjacent to the cure control layer CRC.

As the filling material at the position, which is not adjacent to the cure control layer CRC, is first cured and contracts, the void VD may be provided between the first to third pixel areas PXA-R, PXA-G and PXA-B. As illustrated in FIG. 5, the void VD may have a shape having a curvature on a cross-sectional view. For example, the void VD may have an oval shape, a shape of a convex lens, or the like on a cross-sectional view. However, the shape of the void VD is not limited thereto, and may vary depending on conditions such as type of the cure retardant material, concentration, type of the filling material, curing temperature or time, or the like.

Referring to FIG. 6, the shape of the void VD-a in the case in which the cure control layer CRC-a includes the unevenness on the bottom surface thereof is illustrated as an example. As the cure control layer CRC-a includes the unevenness on the bottom surface thereof, a flow rate of the filling material at a peripheral portion of the unevenness may be lower than a flow rate at an opposite side when the filling material is cured to contract. Here, the peripheral portion of the unevenness may mean a portion adjacent to the unevenness, and the opposite side may mean a portion spaced apart from the unevenness and adjacent to the display panel DP.

As the flow of the filling material is physically adjusted due to the unevenness, the void VD-a may be provided between the first to third pixel areas PXA-R, PXA-G and PXA-B. As illustrated in FIG. 6, the void VD-a may have substantially a trapezoidal shape on a cross-sectional view. The void VD-a may have a top surface adjacent to the cure control layer CRC-a, and a bottom surface adjacent to the display panel DP. The top surface of the void VD-a may correspond to an upper side of the trapezoid, and the bottom surface of the void VD-a may correspond to a lower side of the trapezoid. The width of the upper side of the trapezoid may be greater than the width of the lower side of the trapezoid. The area of the top surface of the void VD-a may be less than the area of the bottom surface thereof on a plan view.

Referring to FIG. 7, the shape of the void VD-b in the case in which the cure control layer CRC-b includes the cure retardant material and also includes the unevenness on the bottom surface thereof is illustrated as an example. Compared to the case described with reference to FIG. 6, the curing of the filling material adjacent to the cure control layer CRC-b may be retarded as the cure control layer CRC-b includes the cure retardant material. Thus, the width of the upper side of the void VD-b having a trapezoidal shape may be greater compared to the case in FIG. 6 of having the same unevenness structure but not including the cure retardant material. The area of the top surface of the void VD-b may be less than the area of the bottom surface thereof on a plan view.

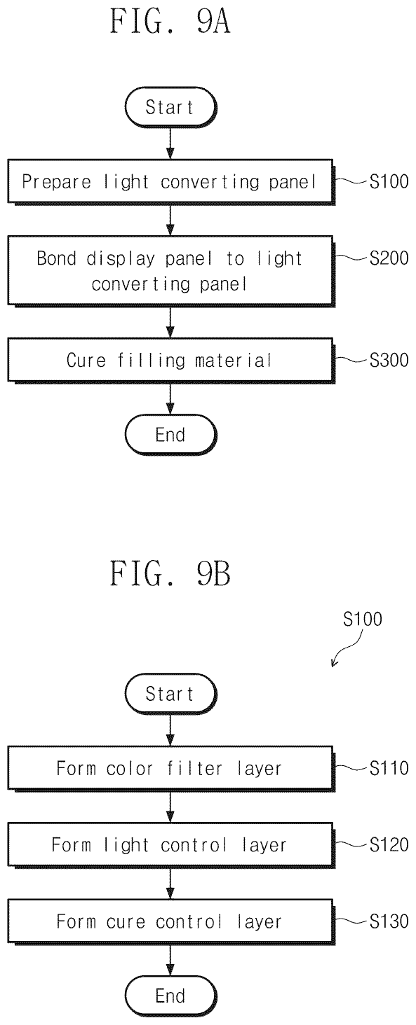

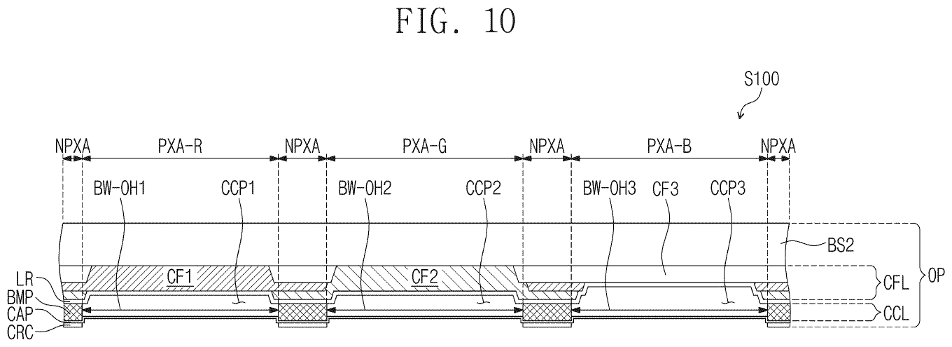

FIGS. 9A and 9B are each a flowchart of a method for manufacturing a display device according to some embodiments of the present disclosure. FIGS. 10 to 13 are each a cross-sectional view illustrating an operation of a method for manufacturing a display device according to some embodiments of the present disclosure.

Referring to FIG. 9A, the method for manufacturing the display device includes preparing a light converting panel (S100), bonding a display panel to the light converting panel with a filling material therebetween (S200), and curing the filling material (S300).

Referring to FIG. 9B, the preparing of the light converting panel (S100) includes forming a color filter layer on a base layer (S110), forming a light control layer on the color filter layer (S120), and forming a cure control layer (S130).

FIG. 10 illustrates an example of the preparing of the light converting panel OP (S100). The light converting panel OP may be prepared by forming a color filter layer CFL on a base layer BS2, forming, on the color filter layer CFL, a light control layer CCL including a division pattern BMP and a plurality of light controllers CCP1, CCP2 and CCP arranged to be spaced apart from each other by the division pattern BMP, and forming a cure control layer CRC on the division pattern BMP. FIG. 10 illustrates that the base layer BS2 is located at an upper side and the light control layer CCL is located at a lower side, in order that the directions are consistent with directions in FIGS. 11 to 13 below.

Each of color filters CF1, CF2 and CF3 of the color filter layer CFL may be formed on the base layer BS2 through a photolithography process, and the same or similar contents described above with reference to FIGS. 5 to 7 may be applied to the color filter layer CFL.

The preparing of the light converting panel (S100) may further include forming a low refractive layer LR on the color filter layer CFL. The low refractive layer LR may be formed through a chemical vapor deposition (CVD), or may be formed by applying an organic matter. The same or similar contents described above with reference to FIGS. 5 to 7 may be applied to the low refractive layer LR. Meanwhile, the forming of the low refractive layer LR may be omitted as necessary.

The forming of the light control layer (S120) may include forming the color filter layer CFL and forming the light controllers CCP1, CCP2 and CCP3.

The division pattern BMP of the light control layer CCL may be formed in a peripheral area NPXA of the color filter layer CFL. Alternatively, as illustrated in FIG. 10, in the case in which the light converting panel OP includes the low refractive layer LR, the division pattern BMP may be formed in a peripheral area NPXA of the low refractive layer LR. The division pattern BMP may be formed through a photolithography process, and the same or similar contents described above with reference to FIGS. 5 to 7 may be applied to the division pattern BMP.

The light controllers CCP1, CCP2 and CCP3 of the light control layer CCL may be formed within opening portions BW-OH1, BW-OH2 and BW-OH3, respectively, which are defined in the splitting pattern BMP. However, embodiments according to the present disclosure are not limited thereto, and an edge of each of the light controllers CCP1, CCP2 and CCP3 may be formed to have at least a portion overlapping the division pattern BMP. The light controllers CCP1, CCP2 and CCP3 may be formed by polymerizing liquid ink compositions, which are provided through an inkjet process, by thermal or optical curing, and the same or similar contents described above with reference to FIGS. 5 to 7 may be applied to the light controllers CCP1, CCP2 and CCP3.

The preparing of the light converting panel OP (S100) may further include forming a capping layer CAP on the light control layer CCL. The capping layer CAP may be formed through a chemical vapor deposition (CVD), and the same or similar contents described above with reference to FIGS. 5 to 7 may be applied to the capping layer CAP. Meanwhile, the forming of the capping layer CAP may be omitted as necessary.

The cure control layer CRC may be formed on the division pattern BMP. The cure control layer CRC may include a cure retardant material as described above. The cure control layer CRC may be formed through a photolithography process. The cure control layers CRC-a and CRC-b in FIGS. 6 and 7, each of which includes the unevenness on the bottom surface thereof, may be formed in the same method. The same or similar contents described above with reference to FIG. 5 may be applied to the cure control layer CRC.

FIG. 11 illustrates an example of the bonding of the display panel DP to the light converting panel OP with the filling material FM therebetween (S200).

The filling material FM may be applied in a liquid state and uniformly dispersed through the bonding of the light converting panel OP and the display panel DP to each other. Thus, as illustrated in FIG. 11, the filling material FM may be dispersed entirely between the light converting panel OP and the display panel DP and on first to third pixel areas PXA-R, PXA-G and PXA-B and the peripheral area NPXA.

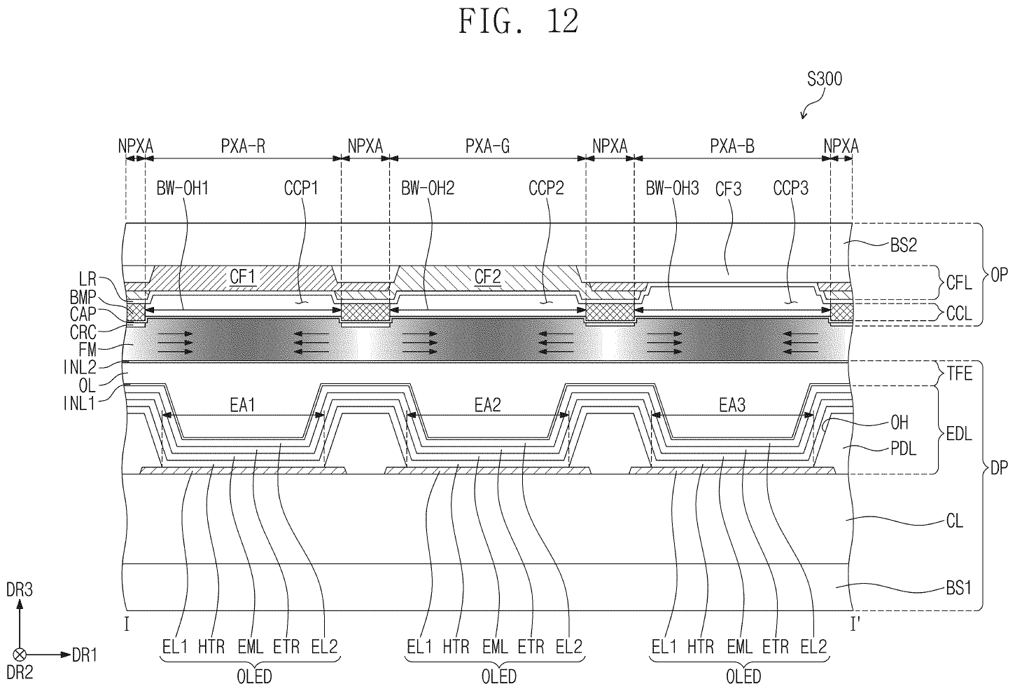

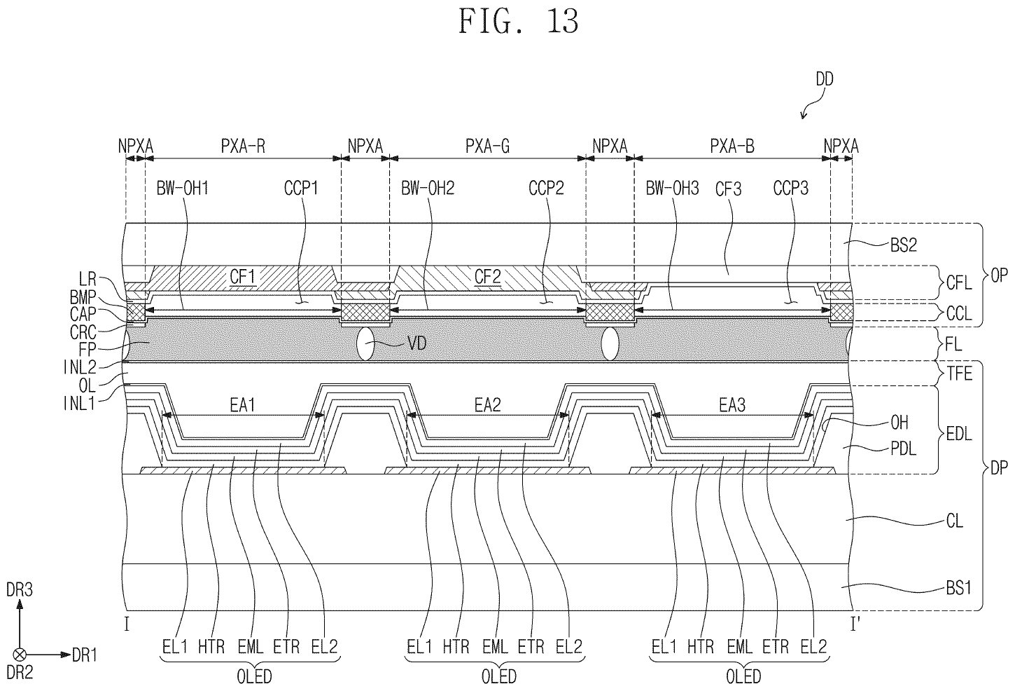

FIG. 12 illustrates an example of the curing of the filling material FM (S300).

The filling material FM applied in the liquid state may change into a solid state through a curing process. For example, a thermal curing process may be applied as the curing process, but the curing process is not limited thereto.

As the cure control layer CRC includes a cure retardant material, initiation of curing of the filling material FM, which is located between the first to third pixel areas PXA-R, PXA-G and PXA-B, at a position adjacent to the cure control layer CRC may be suppressed. That is, the curing of the filling material FM may be retarded compared to the filling material FM, which is located in the first to third pixel areas PXA-R, PXA-G and PXA-B, at a position that is not adjacent to the cure control layer CRC.

The curing of the filling material FM at the position that is not adjacent to the cure control layer CRC may be first initiated, and the filling material FM may contract. In FIG. 12, directions in which the filling material FM at a position corresponding to each of the first to third pixel areas PXA-R, PXA-G and PXA-B is cured to contract are schematically shown by arrows. That is, the filling material FM may contract around a portion that is first cured.

FIG. 13 illustrates an example of a display device DD in which the filling material FM including a filled portion FP and a void VD is formed after the filling material FM is cured.

As a curing rate of the filling material FM (see FIG. 12) is adjusted by the cure control layer CRC, the filling layer FL may be formed by including the filled portion FP and the void VD that is located between the first to third pixel areas PXA-R, PXA-G and PXA-B. The same or similar contents described above with reference to FIG. 5 may be applied to the filled portion FP and the void VD.

According to the foregoing description, the display device according to some embodiments of the present disclosure may include the filling layer having the structure capable of reducing the light losses, thereby relatively improving the light extraction efficiency and the color reproducibility of the display device.

In addition, the method for manufacturing the display device according to some embodiments of the present disclosure may adjust the curing rate in the bonding of the display panel and the light converting panel to each other to cure the filling material, thereby relatively improving the process properties and the mass productivity.

Although the embodiments of the present invention have been described, it is understood that the present invention should not be limited to these embodiments but various changes and modifications can be made by one ordinary skilled in the art within the spirit and scope of the present invention as hereinafter claimed.

Therefore, the technical scope of the inventive concept is not limited to the contents described in the detailed description of the specification, but should be determined by the appended claims, and their equivalents.

What is claimed is:

1. A display device comprising:
a display panel comprising a light emitting element layer;
a light converting panel on the display panel; and
a filling layer between the display panel and the light converting panel,
wherein the light converting panel comprises:
a light control layer comprising a division pattern, and a plurality of light controllers spaced apart from each other by the division pattern; and
a cure control layer below the division pattern.

2. The display device of claim 1, wherein the division pattern and the cure control layer overlap each other in a plan view.

3. The display device of claim 1, wherein the filling layer comprises:
a filled portion overlapping the plurality of light controllers in a plan view; and
a void overlapping the division pattern in the plan view,
wherein the filled portion has a refractive index greater than that of the void.

4. The display device of claim 1, wherein the cure control layer comprises a cure retardant material.

5. The display device of claim 4, wherein the filling layer comprises:
a filled portion overlapping the plurality of light controllers in a plan view; and
a void overlapping the division pattern in the plan view,
wherein the void has a shape having a curvature on a cross section.

6. The display device of claim 4, wherein the filling layer comprises:
a filled portion overlapping the plurality of light controllers in a plan view; and
a void overlapping the division pattern in the plan view,
wherein the void has an oval shape on a cross section.

7. The display device of claim 1, wherein the cure control layer has a top surface adjacent to the division pattern, and a bottom surface adjacent to the filling layer,
wherein the bottom surface of the cure control layer comprises an unevenness.

8. The display device of claim 7, wherein the filling layer comprises:
a filled portion overlapping the plurality of light controllers in a plan view; and
a void overlapping the division pattern in the plan view,
wherein the void has a top surface adjacent to the cure control layer, and a bottom surface adjacent to the display panel,
wherein the top surface of the void has an area less than that of the bottom surface of the void in the plan view.

9. The display device of claim 1, wherein the cure control layer comprises a cure retardant material, and
the cure control layer has a top surface adjacent to the division pattern, and a bottom surface adjacent to the filling layer,
wherein the bottom surface of the cure control layer comprises an unevenness.

10. The display device of claim 9, wherein the filling layer comprises:
a filled portion overlapping the plurality of light controllers in a plan view; and
a void overlapping the division pattern in the plan view,
wherein the void has a top surface adjacent to the cure control layer, and a bottom surface adjacent to the display panel,
wherein the top surface of the void has an area less than that of the bottom surface of the void in the plan view.

11. A method for manufacturing a display device, the method comprising:
preparing a light converting panel;
bonding a display panel to the light converting panel with a filling material therebetween; and
curing the filling material,
wherein the preparing of the light converting panel comprises:
forming a color filter layer on a base layer;
forming, on the color filter layer, a light control layer comprising a division pattern and a plurality of light controllers spaced apart from each other by the division pattern; and
forming a cure control layer on the division pattern.

12. The method of claim 11, wherein the curing of the filling material comprises an operation in which the filling material on the plurality of light controllers is cured and contracts, and the filling material on the division pattern is not cured.

13. The method of claim 11, wherein the curing of the filling material comprises an operation in which a filled portion overlapping the plurality of light controllers in a plan view and a void overlapping the division pattern in the plan view are formed.

14. The method of claim 11, wherein the cure control layer comprises a cure retardant material configured to retard the curing of the filling material.

15. The method of claim 14, wherein the curing of the filling material comprises an operation in which a void overlapping the division pattern in a plan view is formed,
wherein the void has a shape having a curvature in a cross section view.

16. The method of claim 15, wherein the void has an oval shape in the cross section view.

17. The method of claim 11, wherein the cure control layer comprises an unevenness on a surface thereof adjacent to the filling material.

18. The method of claim 17, wherein the curing of the filling material comprises an operation in which a filled portion overlapping the plurality of light controllers in a plan view and a void overlapping the division pattern in the plan view are formed,
wherein the void has a top surface adjacent to the cure control layer, and a bottom surface adjacent to the display panel,
wherein the top surface of the void has an area that is formed to be less than that of the bottom surface of the void in the plan view.

19. The method of claim 11, wherein the bonding of the display panel to the light converting panel comprises applying the filling material.

20. The method of claim 11, wherein, in the forming of the cure control layer, the cure control layer is formed through a photolithography process.
